(19) United States
(12) Patent Application Publication
(10) Pub. No.: US 2019/0044303 A1
(43) Pub. Date: Feb. 7, 2019

(54) SEMICONDUCTOR LASER LIGHT SOURCE DEVICE

(71) Applicant: MITSUBISHI ELECTRIC CORPORATION, Tokyo (JP)

(72) Inventors: Daisuke MORITA, Tokyo (JP); Motoaki TAMAYA, Tokyo (JP); Kazutaka IKEDA, Tokyo (JP); Yumi GENDA, Tokyo (JP)

(73) Assignee: MITSUBISHI ELECTRIC CORPORATION, Tokyo (JP)

(21) Appl. No.: 16/074,605

(22) PCT Filed: Feb. 14, 2017
(86) PCT No.: PCT/JP2017/005259

§ 371 Date: Aug. 1, 2018

(30) Foreign Application Priority Data
Feb. 15, 2016 (JP) 2016-025545

(51) Int. Cl. H01S 5/024; H01S 5/40; H01S 5/042; H01S 5/022

(52) U.S. Cl. CPC H01S 5/02423; H01S 5/4025; H01S 5/02276; H01S 5/02236; H01S 5/02469; H01S 5/0425

(57) ABSTRACT

A semiconductor laser light source device wherein a plate-shaped semiconductor laser array has a first electrode and a second electrode, the first electrode is bonded to an electrode layer of a sub-mount substrate in which the electrode layer is formed on one surface of a substrate formed of electrical insulation material and the sub-mount substrate surface which is a surface opposite to a surface on which the electrode layer is formed is bonded to a heat sink made of metal, and in a region which is formed by projecting the sub-mount substrate to inside of the heat sink from the Y direction, a cooling part wherein a plurality of flat flow channels having a width of 200 μm to 600 μm, a depth of 3 mm to 5 mm are aligned at a pitch equal to or less than 1 mm is formed.

### TECHNICAL FIELD

The present invention relates to a semiconductor laser light source device on which a semiconductor laser array having a plurality of semiconductor laser elements which are aligned in an array form is placed.

### BACKGROUND ART

In a semiconductor laser light source device on which a semiconductor laser array having a plurality of semiconductor laser elements which are aligned in an array form is placed, when electric current is supplied to a semiconductor laser array, a semiconductor laser array is an oscillation source of laser light and also a heat source which generates large heat. Regarding a semiconductor laser array, an oscillation wave-length changes depending on a temperature, when it becomes a high temperature, output of laser is reduced, as a result, reliability is also reduced. Consequently, in order to maintain a temperature inside a semiconductor laser array to be proper, it is preferable to provide a cooling structure.

The configuration of a semiconductor laser light source having a cooling structure is disclosed in Patent Document 1, for example. According to the Patent Document 1, on a heat sink having a micro channel for flowing cooling water, a semiconductor laser array is bonded with conductive paste such as solder. A heat sink is configured by layering a thin plate of Cu (Cu, thermal conductivity is 398 W/(m*k))and a thin plate of molybdenum (Mo, thermal conductivity is 140 W/(m*k), and has a linear expansion coefficient of 8 ppm/K. According to the above mentioned configuration, exhaust heat which is generated when a semiconductor laser array oscillates at high output can be effectively dissipated, and heat stress which is generated when a semiconductor laser array is mounted can be reduced.

### PRIOR ART DOCUMENT

### Patent Document

Patent Document 1 JP 2012-222130A

### SUMMARY OF THE INVENTION

### Problems to be Solved by the Invention

However, a semiconductor laser light source device disclosed in the Patent Document 1 has the above mentioned micro channel of a heat sink, therefore, in order to secure a stable exhaust heat performance, a high water velocity is necessary. Therefore, in a case of a low water velocity, a stable exhaust heat performance cannot be secured, as a result, there is a problem such that a long-term reliability as a semiconductor laser light source cannot be obtained.

In order to solve the above-mentioned problem, present invention is made and an objective of present invention is to provide a semiconductor laser light source device whose long-term reliability can be improved.

### Means for Solving Problems

In a semiconductor laser light source device according to present invention, a plate-shaped semiconductor laser array, which has a plurality of semiconductor laser elements that are aligned in an array form, has a first electrode that is formed on one surface and a second electrode that is formed on the other surface, the first electrode is bonded to an electrode layer of a sub-mount substrate in which the electrode layer is formed on one surface of a substrate formed of electrical insulation material and the sub-mount substrate surface which is a surface opposite to a surface on which the electrode layer is formed is bonded to a heat sink made of metal,

in a case where a direction which is perpendicular to a surface on which the sub-mount substrate is bonded is defined as a Y direction, a direction which is perpendicular to the Y-direction and where a plurality of laser elements of the semiconductor laser array are aligned is defined as an X direction and a direction which is perpendicular to the Y direction and the X direction is defined as a Z direction,

in a region which is formed by projecting the sub-mount substrate to inside of the heat sink from the Y direction, a cooling part wherein a plurality of flat flow channels having a width of 200 μm to 600 μm in the Z direction, a depth of 3 mm to 5 mm in the Y direction are aligned at a pitch equal to or less than 1 mm in the Z direction is formed, and in order for cooling water to flow from one side of the X direction of the cooling part to the other, two cooling water channels for communicating with the cooling part from outside of the heat sink are provided.

### Effect of the Invention

According to present invention, a semiconductor laser light source whose long-term reliability can be improved can be obtained.

### BRIEF DESCRIPTION OF THE DRAWINGS

FIG. 1 is a perspective view showing the configuration of a semiconductor laser light source device according to Embodiment 1 of present invention.

FIG. 2A and FIG. 2B are sectional side views showing the configuration of a semiconductor laser light source device according to Embodiment 1 of present invention.

FIG. 3 is an enlarged perspective view showing the vicinity of a laser emission surface of a semiconductor laser light source device according to Embodiment 1 of present invention.

FIG. 4 is a sectional view showing the shape of a water channel inside a heat sink of a semiconductor laser light source device according to Embodiment 1 of present invention.

FIG. 5 is a drawing for describing effect of present invention.

FIG. 6 is another drawing for describing effect of present invention.

FIG. 7 is a perspective view showing the configuration of a semiconductor laser light source device according to Embodiment 2 of present invention.

FIG. 8 is a sectional side view showing the configuration of a semiconductor laser light source device according to Embodiment 2 of present invention.

FIG. 9 is a sectional plan view showing the configuration of a semiconductor laser light source device according to Embodiment 2 of present invention.

FIG. 10 is a perspective view showing the configuration of a semiconductor laser light source device according to Embodiment 3 of present invention.

FIG. 11 is a sectional side view showing the configuration of a semiconductor laser light source device according to Embodiment 3 of present invention.

FIG. 12 is an enlarged perspective view showing the vicinity of a laser emission surface of a semiconductor laser light source device according to Embodiment 3 of present invention.

FIG. 13 is a perspective view showing the configuration of a semiconductor laser light source device according to Embodiment 4 of present invention.

FIG. 14 is a sectional side view showing the configuration of a semiconductor laser light source device according to Embodiment 4 of present invention.

FIG. 15 is a sectional side view showing the configuration of a semiconductor laser light source device according to Embodiment 5 of present invention.

FIG. 16 is a sectional side view showing the configuration of a semiconductor laser light source device according to Embodiment 6 of present invention.

### EMBODIMENTS FOR CARRYING OUT THE INVENTION

In the following, embodiments of a semiconductor laser light source device of present invention will be described referring figures. Regarding a direction, a direction shown in a figure will be reference. Further, present invention will not be limited by following embodiments.

### Embodiment 1

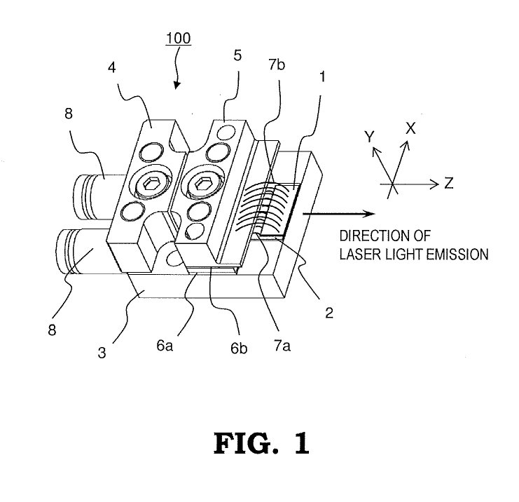

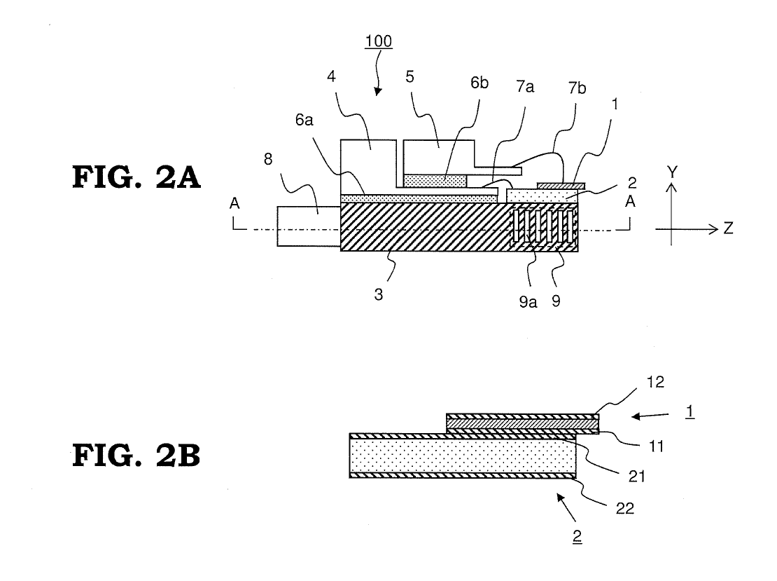

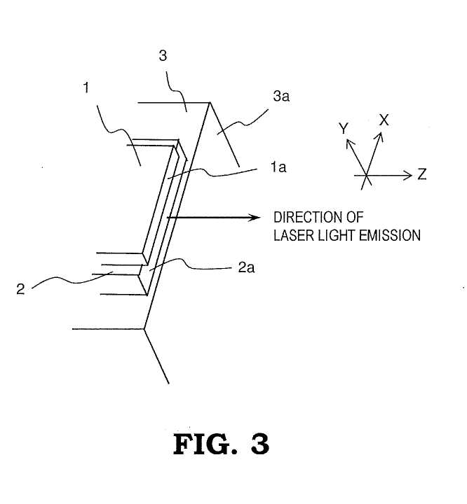

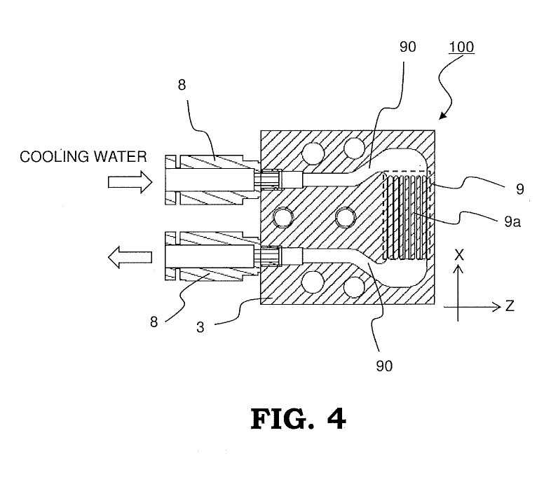

FIG. 1 is a perspective view showing the configuration of a semiconductor laser light source device according to Embodiment 1 of present invention. FIG. 2A and FIG. 2B are sectional side views showing a semiconductor laser light source device according to Embodiment 1 of present invention in an X-direction central part of FIG. 1. FIG. 2A is a sectional view showing the whole of a semiconductor laser light source device and FIG. 2B is a sectional view showing a part of a semiconductor laser array 1 and a sub-mount substrate 2 which are enlarged. FIG. 3 is an enlarged perspective view showing the vicinity of a laser emission surface of a semiconductor laser light source device according to Embodiment 1 of present invention. FIG. 4 is a sectional view taken from line A-A of FIG. 2A showing the shape of water channels inside a heat sink of a semiconductor laser light source device according to Embodiment 1 of present invention.

A semiconductor laser light source device 100 according to Embodiment 1 comprises a heat sink 3, a sub-mount substrate 2 which is bonded on the heat sink 3, a semiconductor laser array 1 which is bonded on the sub-mount substrate 2, a first electrode plate 4 which is fixed on the heat sink 3 via a first insulation plate 6a and a second electrode plate 5 which is fixed on the first electrode plate 4 via a second insulation plate 6b. The semiconductor laser array 1 and the second electrode plate 5 are electrically connected by metallic wires 7b, and the sub-mount substrate 2 and the first electrode plate 4 are electrically connected by metallic wires 7a and the first electrode plate 4 and the second electrode plate 5 constitute a feeding path to the semiconductor laser array 1. Further, the heat sink 3 has a cooling part 9 inside and the heat sink 3 has the configuration in which cooling water can be supplied from outside via water channel coupling members 8 which is connected to a cooling water entrance and a cooling water exit.

In order to effectively radiate heat which is generated by the semiconductor laser array 1 when the semiconductor laser array 1 oscillates, the heat sink 3 is manufactured using a material having excellent thermal conductivity such as a metallic material, for example, a copper (hereinafter, will be referred as Cu), etc.

The sub-mount substrate 2 is manufactured by using a material having excellent thermal conductivity and excellent electrical insulation, for example, a ceramic material such as an aluminum nitride (hereinafter will be referred as AlN) or a silicon carbide (hereinafter will be referred as SiC) is used. On an upper surface of the sub-mount substrate 2, an electrode layer 21 laminated by plating titanium (hereinafter will be referred as Ti), Cu, nickel (hereinafter will be referred as Ni) and gold (hereinafter will be referred as Au) from the lower layer and the conductive electrode layer 21 constitutes a feeding path of the semiconductor laser array 1.

Further, on an upper surface of the electrode layer 21 which is layered on an upper surface of the sub-mount substrate 2, along an edge part 2a at a longer side of the sub-mount substrate 2 shown in FIG. 3, a mounting region of the semiconductor laser array 1 is set, from the lower layer, platinum (hereinafter will be referred as Pt), Au—Sn based solder material or Sn based solder material are laminated by vapor deposition. In the mounting region, the semiconductor laser array 1 is bonded by soldering so as for an edge part la at a longer side which is a side of emission surface of the semiconductor laser array 1 to be a position which is protruded 0 to 30 μm in +Z direction with regard to an edge part 2a of the sub-mount substrate 2. By the above mentioned configuration, in a case where a laser of the semiconductor laser array 1 oscillates, it can prevent for a laser light from hitting the sub-mount substrate 2 and being shaded.

Further, on a lower surface of the sub-mount substrate 2, in the same way as that of on an upper surface, a layer 22, which is made by plating of Ti, Cu, Ni and Au from the lower layer of the substrate, is formed, between the heat sink 3 and the sub-mount substrate 2, by using a soldering sheet which is supplied from outside (not shown in Fig.), the sub-mount substrate 2 is bonded by soldering. The sub-mount substrate 2 is arranged so as for the edge part 2a of the sub-mount substrate 2 to be a position which is shifted back 0 to 30 μm in −Z direction from an edge part 3a on the heat sink 3. Further, on a lower surface of the sub-mount substrate 2, an Au—Sn based solder material or a Sn based solder material, which is the same as that of an upper surface, may be deposited so as to be bonded by soldering using a solder material which is deposited.

The semiconductor laser array 1 is a semiconductor laser in which a plurality of semiconductor laser elements are aligned in an array form, and on an upper surface and a lower surface, Au electrodes are provided. An Au electrode which is provided in a lower surface may be referred as a first electrode 11 and an Au electrode which is provided in an upper surface may be referred as a second electrode 12. As above mentioned, an Au electrode 11 (a first electrode) which is provided on a lower surface of the semiconductor laser array 1 is electrically and mechanically bonded to the sub-mount substrate 2 by soldering using a solder material which is deposited to an upper surface of the sub-mount substrate 2. The first insulation plate 6a and the second insulation plate 6b are made of a material having electrical insulation, for example, glass material, peak material, ceramic material, etc. is used. Further, in the specification of present invention, as shown in each figure, a direction which is perpendicular to a surface, of the heat sink 3, to which the sub-mount substrate 2 is bonded is defined as a Y direction, a direction which is perpendicular to the Y direction and in which a plurality of semiconductor laser elements of the semiconductor laser array 1 are aligned is defined as an X direction and a direction which is perpendicular to the Y direction and the X direction is defined as a Z direction. Further, the forward Z direction is the direction in which a laser light travels.

On a back side (−Z direction) of the sub-mount substrate 2 which is bonded on the heat sink 3, the first insulation plate 6a is fixed with a screw so as to be sandwiched by the first electrode plate 4 and the heat sink 3. Regarding a screw to be used, a screw made of an insulation material, for example, a resin screw or a ceramic screw may be used, or by inserting an insulation bush (not shown in the figure) to a part where the first electrode plate 4 contacts with a screw, the heat sink 3 and the first electrode plate 4 are electrically insulated. A position of the first insulation plate 6a and the first electrode plate 4 are determined by a locating pin (not shown in the figure) which is lightly press-fitted to the heat sink 3. A locating pin is made of insulation material, for example, a resin pin or a ceramic pin may be used. It is possible to fix by bonding with bonding material or solder material, however, it is preferable to be fixed with a screw from a view point such that a component can be easily disconnected. Further, in a case where solder material is used, by using solder material having a melting point which is lower than that of solder material which is deposited to the sub-mount substrate 2, in a case where the sub-mount substrate 2 is already bonded, by re-melting solder materials on an upper surface and a lower surface of the sub-mount substrate 2, the semiconductor laser array 1 or the sub-mount substrate 2 can be prevented from being shifted from a position, with regard to a position on the heat sink 3.

On the first electrode plate 4, the second insulation plate 6b is fixed with a crew so as to be sandwiched by the first electrode plate 4, the first insulation plate 6a and the heat sink 3 which are already fixed and the second electrode plate 5. Regarding the other fixing method, description will be omitted because other fixing method will be same as that of the first insulation plate 6a.

The first electrode plate 4 which is fixed on the first insulation plate 6a and the second electrode plate 5 which is fixed on the second insulation plate 6b are manufactured by using material having high electrical conductivity such as Cu, the first electrode plate 4 and the second electrode plate 5 have a thickness which is sufficiently thicker (for example, several mm thickness) than that of a plating layer, and have the structure having extremely small electrical resistance, and on whole of a surface, an Au layer is layered by plating process.

The first electrode plate 4 have an L shape which is viewed from a side surface, and are arranged in parallel to a longer side direction (an X direction) of the sub-mount substrate 2 without being contacted and having a predetermined clearance, and the first electrode plate 4 and the sub-mount substrate 2 are electrically connected by the metallic wires 7a. At this time, a predetermined clearance is provided between the metallic wires 7a and the second electrode plate 5 by the second insulation plate 6b so as not to be contacted. As the metallic wires 7a, for example, Au wires or Au ribbons having a large line width or Cu ribbons can be used. The metallic wires 7a are bonded before the second insulation plate 6b is arranged.

The second electrode plate 5 has an L shape which is viewed from a side surface, and is electrically connected to the second electrode 12 which is formed on an upper surface of the semiconductor laser array 1 by the metallic wires 7b. In the same way as that of the metallic wires 7a, as the metallic wires 7b, wires made of material such Au or ribbons having large line width can be used.

In the heat sink 3, a cooling part 9 is formed, from two cooling water channels 90, which are provided at both sides of the cooling part 9, to communicate to outside of the heat sink 3, via a cooling water channel coupling member 8, the cooling part 9 is connected to a cooling water circulating device (not shown in the figure) which can control a cooling water temperature to be fixed temperature. The above mentioned configuration has a configuration in which cooling water is circulated between the cooling part 9 in the heat sink 3 and a cooling water circulating device, a temperature of cooling water which passes through the cooling part 9 is controlled, and mainly, when cooling water flows in the cooling part 9 in an X-direction, heat which is generated by the semiconductor laser array 1 is exhausted.

A channel in the cooling water part 9 comprises a flat flow channel 9a having a flow channel width (size in a Z direction) of 200 to 600 μm and a flow channel depth (size in a Y direction) of 3 to 5 mm and having an aspect ratio which is larger than 5, and the flat flow channels 9a are aligned with a pitch which is smaller than 1 mm or less in a width direction (Z direction). The cooling part 9 is formed in a region where the sub-mount substrate 2 is projected to inside of the heat sink from a Y direction, and a length of each flat flow channel 9a (X-direction) and the number of the flat flow channels 9a which are aligned in a Z-direction are set so as to include a region where the sub-mount region 2 is projected.

Next, a series of process for assembling the semiconductor laser light source device 1 will be described. First, on the sub-mount substrate 2, with reference to the edge part 2a of the sub-mount substrate 2, the semiconductor laser array 1 is placed on a position where the edge part la of the semiconductor array 1 is protruded 0 to 30 μm in +Z direction. After that, by melting Au—Sn based solder material which is formed on an upper surface of the sub-mount substrate 2 beforehand, the first electrode 11 which is formed on a lower surface of the semiconductor laser array 1 is bonded on the sub-mount substrate 2.

Next, on the heat sink 3, a sheet-shaped solder (not shown in Figure) is placed, with reference to the edge part 3a of the heat sink 3, the sub-mount substrate 2 is placed on a position where the edge part 2a of the sub-mount substrate 2 is shifted back 0 to 30 μm in −Z direction, by melting a sheet-shaped solder which is inserted between the heat sink 3 and the sub-mount substrate 2, the sub-mount substrate 2 is bonded on the heat sink 3. A sheet-shaped solder to be used should have a melting point which is lower than that of solder material which is formed on an upper surface of the sub-mount substrate 2 beforehand. Further, instead of a sheet-shaped solder, a material in which solder material is deposited on the heat sink 3 beforehand may be used.

Next, the first electrode plate 4 is fixed with a screw at back side (−Z direction) of the sub-mount substrate 2 which is bonded on the heat sink 3, by using a screw hole which is formed on the heat sink 3, via an electrical insulation bush (not shown in Figure), the first electrode plate 4 and the first insulation plate 6a are fixed on the heat sink 3 by one operation. After that, an upper surface of the electrode layer 21 of the sub-mount substrate 2 and the first electrode plate 4 are connected by using the metallic wires 7a.

Next, by using a screw hole which is provided on the heat sink 3, via an electrical insulation bush (not shown in Figure), on the heat sink 3, the second electrode plate 5 and the second insulation plate 6b are fixed with a screw by one operation. After that, the second electrode plate 5 and the second electrode 12 which is formed on an upper surface of the semiconductor laser array 1 are connected by using the metallic wires 7b. The water channel coupling members 8 are fixed to the heat sink 3 with screws. Before the sub-mount substrate 2 is bonded, the water channel coupling members 8 may be fixed to the heat sink 3 by brazing or by shrink fitting.

Next, a laser oscillation operation will be described. A case in which the semiconductor laser array 1 is mounted with junction (anode) down will be described as an example. Further, in a case where the semiconductor laser array is mounted with junction up, only a direction of a feeding path will be reverse, however, the configuration and effect will not be changed.

In a case where the semiconductor laser array 1 is mounted with junction-down, electric current which is supplied from an electric power source (not shown in Figure) flows from an electric power source to the first electrode plate 4, the metallic wires 7a, the sub-mount substrate 2 (the electrode plate 21 which is layered on an upper surface), the semiconductor laser array 1, the metallic wires 7b, the second electrode plate 5 and the electric power source so as to oscillate the semiconductor laser array 1.

Regarding conventional micro channels, in order to improve the heat transmission ratio between a flow channel wall and cooling water, it is necessary to make the flow velocity to be 2 to 5 m/s. However, inventors of present invention found out such that in a case where the flow velocity is large and the speed of the flow of cooling water is fast, due to erosion of a heat sink which is caused by cooling water, there is apprehension regarding long term reliability of laser light source device. Then, the inventors of present invention pursue the configuration in which exhaust heat performance can be secured even when the flow velocity is small and the speed of the flow of cooling water is slow, and found out the configuration in which exhaust heat performance can be secured in the condition where the flow velocity is small.

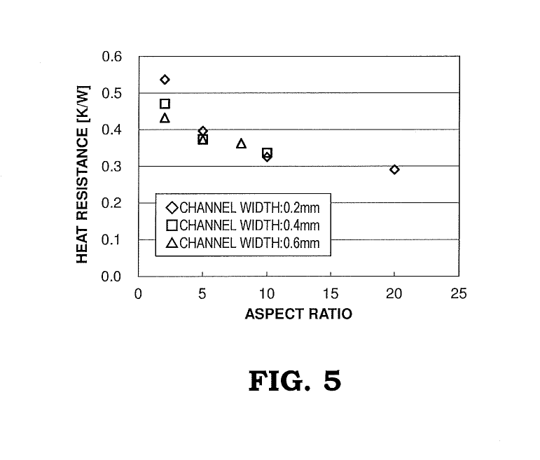

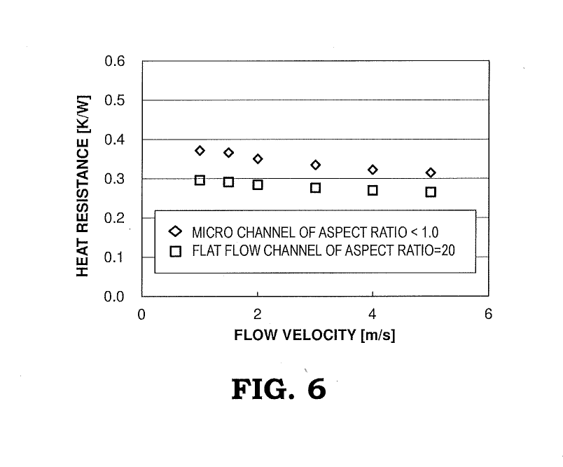

FIG. 5 shows the result which is obtained by calculating heat resistance between cooling water and the semiconductor laser array 1 with respect to an aspect ratio which is expressed by ratio of a flow channel width of the flat flow channel 9a (size in Z direction) to a flow channel depth of the flat flow channel 9a (size in Y direction) when cooling water is flown at the flow velocity of 1.5 m/s. Further, FIG. 6 is a graph showing effect according to an embodiment of present invention, and shows the result which is obtained by calculating heat resistance between a heat sink comprising a conventional micro channel having an aspect ratio which is lower than 1 and a heat sink comprising a flat flow channel according to Embodiment 1 of present invention with respect to the flow velocity of cooling water. An example of calculation of a flat flow channel according to embodiment of present invention is a case in which a flow channel width is 200 μm, a depth is 4 mm and an aspect ratio is 20.

In FIG. 5, it is found out such that a value of heat resistance increases in accordance with decrease of an aspect ratio, especially, when an aspect ratio is 5 or lower, a value of heat resistance increases remarkably. Further, in FIG. 6, a semiconductor laser light source device having conventional general micro channels and a semiconductor laser light source device according to the embodiment of present invention are compared. It is found out such that in a semiconductor laser light source device according to embodiments of present invention, the cooling part 9 comprising the flat flow channel 9a is employed, therefore exhaust heat area becomes large, as a result, at the flow velocity of 1.0 m/s, a semiconductor laser light source device according to embodiment of present can have exhaust heat performance which is same or more excellent than that of a semiconductor laser light source device having conventional general micro channels when cooling water is flow at the flow velocity of 5.0 m/s. As above mentioned, according to the embodiment of present invention, even at the flow velocity which is 2.0 m/s or lower, exhaust heat performance can be secured, and because the flow velocity becomes small, erosion (corrosion), which advances more when the flow velocity is larger, can be prevented.

Conventionally, heat resistance is made to be small by the configuration in which flow channels having a small aspect ratio which is referred as micro channel are aligned so as to increase the flow velocity. It is considered such that the above mentioned is performed in order to make a device to be compact as much as possible. However, erosion (corrosion) advances when the flow velocity is large, therefore, reliability of a device is sacrificed. On the other hand, the inventors of present invention found out such the configuration in which erosion can be controlled and heat resistance is not changed from that of conventional configuration by increasing an aspect ratio of a flow channel and increasing a thickness of a heat sink only several mm.

Further, according to a semiconductor laser light source device of Embodiment 1 of present invention, the semiconductor laser array 1 is mounted on the sub-mount substrate 2 having electrical insulation and high heat transmission ratio, the first electrode plate 4 is mounted on the first insulation plate 6a having electrical insulation, the second electrode plate 5 is mounted on the second insulation plate 6b having electrical insulation, between the first electrode plate 4, the metallic wires 7a, the sub-mount substrate 2, the semiconductor laser array 1, the metallic wires 7b and the second electrode plate 5, a feeding path is constituted. As above mentioned, by electrically separating a feeding path and the cooling part 9, influence of electric corrosion can be eliminated and the long-term reliability can be improved.

### Embodiment 2

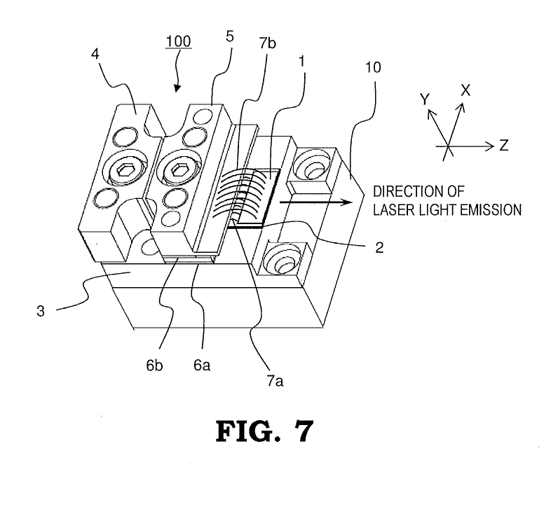

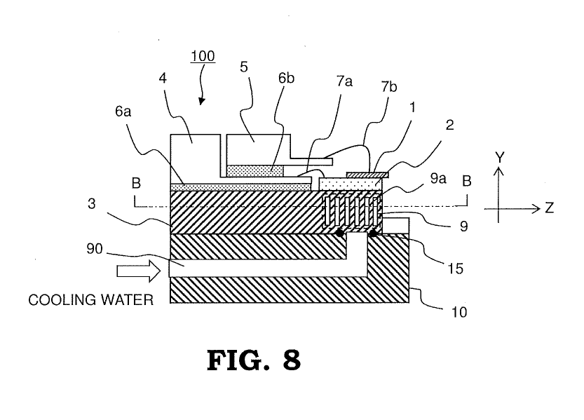

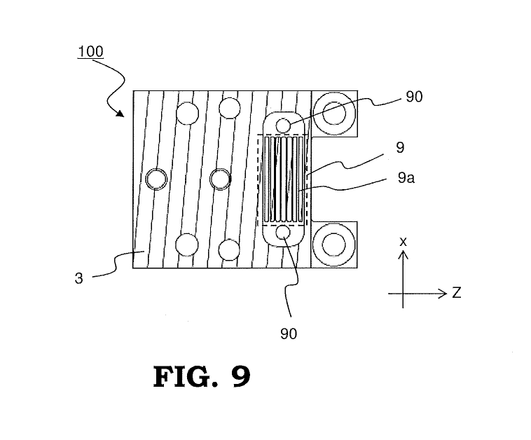

FIG. 7 is a perspective view showing a semiconductor laser light source device according to Embodiment 2 of present invention. FIG. 8 is a sectional side view in an X-direction central part in FIG. 7 showing a semiconductor laser light source device according to Embodiment 2 of present invention. FIG. 9 is a sectional view taken from line B-B of FIG. 8 showing the shape of water channel inside a heat sink of a semiconductor laser light source device according to Embodiment 2 of present invention. Regarding a semiconductor laser light source device according to Embodiment 2 of present invention, in comparison with that of Embodiment 1, a method for supplying cooling water to a cooling part 9 is different. In the same way as that of Embodiment 1, the cooling part 9 comprises a plurality of flat flow channels 9a and two cooling water channels 90 which communicate with a bottom surface of a heat sink 3, respectively, from both sides of the cooling water part 9 are provided. Cooling water is supplied from a cooling water block 10 via the cooling water channel 90. Further, between the heat sink 3 and the cooling water block 10, a water channel sealing member 15 for preventing water leak is inserted. An elastic annular packing (O-ring) made of rubber is used for the water channel sealing member 15. Other configuration is same as that of Embodiment 1, therefore, description regarding the configuration to which the same number is given will be omitted. A series of process for assembling a semiconductor laser light source device are same as those of Embodiment 1, therefore, description will be omitted. Laser oscillation operation is also same as that of Embodiment 1, therefore, description will be omitted.

Regarding a semiconductor laser light source according to Embodiment 2 of present invention, in addition to effect of Embodiment 1 of present invention, a water channel coupling member 8 is not necessary, therefore, a depth (a size in a Z direction) of a semiconductor laser light source device can be shortened. Further, when a length of water channel inside of the heat sink 3 is shortened, pressure loss when cooling water passes inside a water channel is reduced, as a result, a cooling water circulation device whose size is smaller than that of Embodiment 1 can be used.

### Embodiment 3

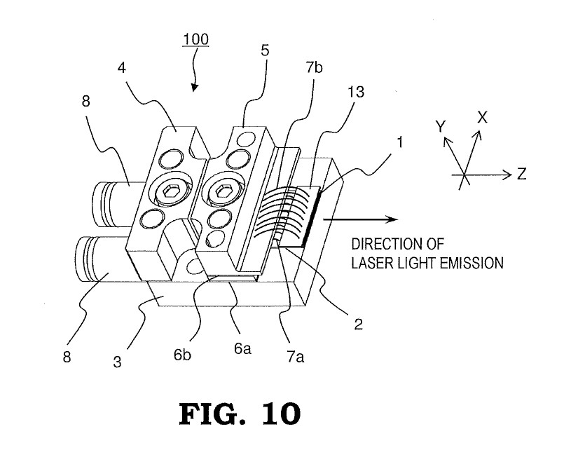

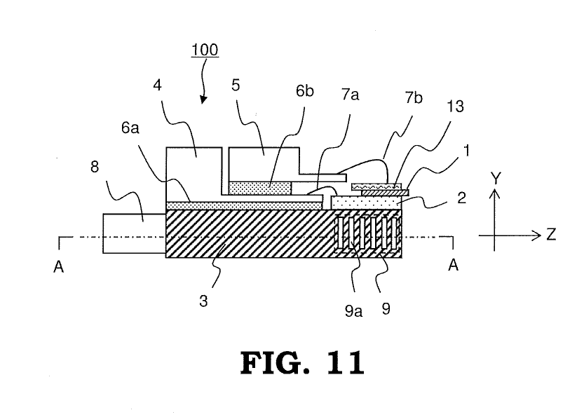

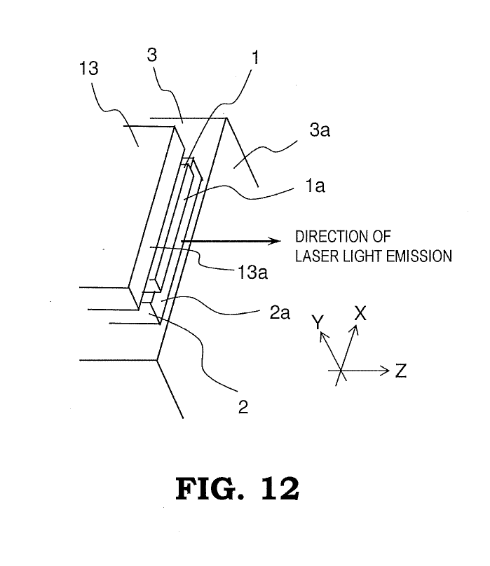

FIG. 10 is a perspective view showing a semiconductor laser light source device according to Embodiment 3 of present invention. FIG. 11 is a sectional side view showing a semiconductor laser light source device according to Embodiment 3 of present invention in an X-direction central part in FIG. 10. FIG. 12 is an enlarged perspective view showing the vicinity of a laser emission surface of a semiconductor laser light source device according to Embodiment 3 of present invention. In comparison with Embodiment 1, a semiconductor laser light source device according to Embodiment 3 of present invention is different on the point such that a second electrode 12 (refer to FIG. 2B) which is formed on an upper surface of a semiconductor laser array 1 is bonded on an indirect substrate 13.

The indirect substrate 13 is made of a material including a cupper-tungsten (hereinafter, will be referred as CuW) having a linear expansion coefficient (a linear expansion coefficient: 6.0 to 8.3×10⁻⁶/K) which is close to that of the semiconductor laser array 1 (5.9×10⁻⁶/K) and has high heat transmission ratio (170 W/mk) and high electrical conductivity. On one surface at a side of the semiconductor laser array 1 of the indirect substrate 13, an Au—Sn based solder material or a Sn based solder material is deposited, and the second electrode 12 of the semiconductor laser array 1 is bonded by soldering with the Au—Sn based solder material or the Sn based solder material which is deposited to the indirect substrate 13. Because the indirect substrate 13 has a linear expansion coefficient which is close to that of the second electrode 12, the indirect substrate 13 functions for relaxing stress of the semiconductor laser array 1 when it is bonded, and the indirect substrate 13 has electrical conduction, as a result, the second electrode 12 of the semiconductor laser array 1 and an upper surface of the indirect substrate 13 are electrically connected.

Unlike Embodiment 1, metallic wires 7b electrically connect an upper surface of the indirect substrate 13 and the second electrode plate 5. Other configuration is same as that of Embodiment 1, therefore, description regarding the configuration to which the same number is given will be omitted. Regarding a series of process for assembling a semiconductor laser light source device, only a different process will be described. Other process is same as that of Embodiment 1, therefore, description will be omitted.

The semiconductor laser array 1 is placed on the sub-mount substrate 2, with reference to an edge part 2a of the sub-mount substrate, so as for an edge part la of the semiconductor laser array 1 to be protruded 0 to 30 μm in +Z direction, and the indirect substrate 13 is placed on the semiconductor laser array 1, with reference to an edge part la of the semiconductor laser array 1, so as for an edge part 13a of the indirect substrate to be protruded 0 to 30 μm in −Z direction. After that, an Au—Sn based solder material which is formed on an upper surface of the sub-mount substrate 2 beforehand, an Au—Sn based solder material which is formed on a back part of the indirect substrate 13 beforehand are melted, and the semiconductor laser array 1 is bonded on the sub-mount substrate 2 and the indirect substrate 13 is bonded on the semiconductor laser array 1. In the same way as that of Embodiment 1, after the second electrode plate 5 is mounted, by using metallic wires 7b, the second electrode plate 5 and the indirect substrate 13 are electrically connected. Laser oscillation operation is same as that of Embodiment 1, therefore, description will be omitted.

Regarding a semiconductor laser light source device according to Embodiment 3, in addition to effect of Embodiment 1, by bonding the indirect substrate 13 on the semiconductor laser array 1, due to the indirect substrate 13 having high heat transmission ratio (170 W/mK), heat which is generated by the semiconductor laser array 1 is transmitted on an XZ plane, therefore, a temperature distribution which is generated on an XZ plane of the semiconductor laser array 1 is relaxed. Further, because the indirect substrate 13 has electrical conductivity, in a case where the indirect substrate 13 is not provided, depending on a position where the metallic wires 7a which is connected on the semiconductor laser array 1, an electrical distribution which is generated in an XZ plane of the semiconductor laser array 1 is relaxed. As above mentioned, when a temperature distribution and an electrical distribution in the semiconductor laser array 1 are relaxed, thermal load and electrical load to a plurality of laser elements which are aligned in an array becomes uniform, damage which is caused by high load to specific semiconductor laser element among a plurality of semiconductor laser elements can be controlled, as a result, a life as a semiconductor laser light source device can be prolonged.

### Embodiment 4

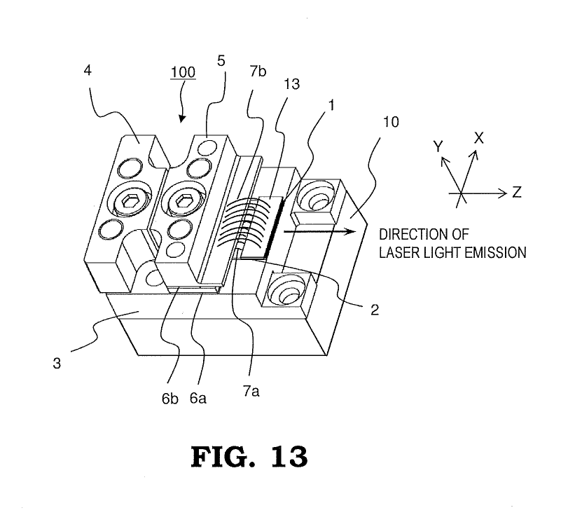

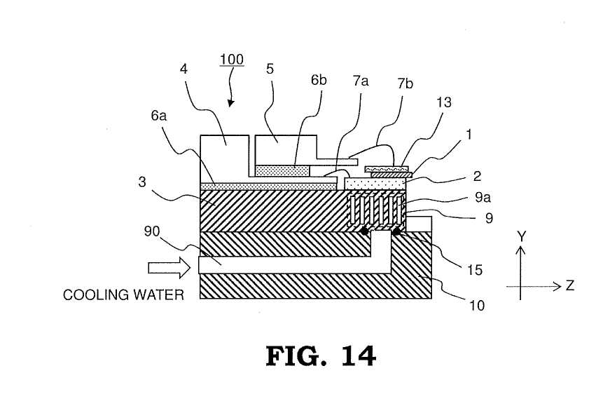

FIG. 13 is a perspective view showing a semiconductor laser light source device according to Embodiment 4 of present invention. FIG. 14 is a sectional side view in an X-direction central part in FIG. 13 showing a semiconductor laser light source device according to Embodiment 4 of present invention. In comparison with Embodiment 2, a semiconductor laser light source device according to Embodiment 4 of present invention is different on the point such that an indirect substrate 13 is bonded on a second electrode 12 which is formed on an upper surface of a semiconductor laser array 1. An indirect substrate 13 is placed at a position, with reference to an edge part of a sub-mount substrate 2, for an edge part of the indirect substrate 13 to coincide with a Z direction, further, with reference to an edge part of the indirect substrate 13, for an edge part at a longer side of the semiconductor laser array 1 to be protruded 0 to 30 μm in +Z direction. Further, by metallic wires 7b, the indirect substrate 13 and a second electrode 5 are electrically connected. Other configuration is same as that of Embodiment 2, therefore, description of the configuration to which the same number is given will be omitted.

The indirect substrate 13 is made of a material including a cupper-tungsten (hereinafter, will be referred as CuW) having a linear expansion coefficient (a linear expansion coefficient: 6.0 to 8.3×10⁻⁶/K) which is close to that of the semiconductor laser array 1 (5.9×10⁻⁶/K) and has high heat transmission ratio (170 W/mk) and electrical conductivity. On one surface at a side of the semiconductor laser array 1 of the indirect substrate 13, an Au—Sn based solder material or a Sn based solder material is evaporated, by soldering with the Au—Sn based solder material or the Sn based solder material which is deposited to the indirect substrate 13, the indirect substrate 13 is bonded on the semiconductor laser array 1. Because the indirect substrate 13 has a coefficient of thermal expansion which is close to that of the second electrode, the indirect substrate 13 functions for relaxing stress of the semiconductor laser array 1 when it is bonded, and the indirect substrate 13 has electrical conduction, as a result, the second electrode of the semiconductor laser array 1 and an upper surface of the indirect substrate 13 are electrically connected.

Regarding a series of process for assembling a semiconductor laser light device, only the process which is different from that of Embodiment 2 will be described. Other process is same as that of Embodiment 2, therefore description will be omitted. The semiconductor laser array 1 is placed on the sub-mount substrate 2, with reference to an edge part of the sub-mount substrate 2, with reference to an edge part of the sub-mount substrate 2, so as for an edge part of the semiconductor laser array 1 to be protruded 0 to 30 μm in +Z direction, and the indirect substrate 13 is placed on the semiconductor laser array 1, with reference to an edge part of the semiconductor laser array 1, so as for an edge part of the indirect substrate 13 to be shifted back 0 to 30 μm in −Z direction. After that, an Au—Sn based solder material which is formed on an upper surface of the sub-mount substrate 2 beforehand and an Au—Sn based solder material which is formed on a back part of the indirect substrate 13 beforehand are melted, and the semiconductor laser array 1 is bonded on the sub-mount substrate 2 and the indirect substrate 13 is bonded on the semiconductor laser array 1, respectively. In the same way as that of Embodiment 1, after the second electrode plate 5 is mounted, by using metallic wires 7b, the second electrode plate 5 and the indirect substrate 13 are electrically connected. Laser oscillation operation is same as that of Embodiment 1, therefore, description will be omitted.

Regarding a semiconductor laser light source device according to Embodiment 4, in addition to effect of Embodiment 2, by mounting the indirect substrate 13 on the semiconductor laser array 1, due to heat transmission ratio of the indirect substrate 13, heat which is generated by the semiconductor laser array 1 is transmitted on an XZ plane, therefore, a temperature distribution which is generated on an XZ plane of the semiconductor laser array 1 is relaxed. Further, because the indirect substrate 13 has electrical conductivity, in a case where the indirect substrate 13 is not provided, depending on a position where the metallic wires 7a which are connected on the semiconductor laser array 1, an electrical distribution which is generated in an XZ plane of the semiconductor laser array 1 is relaxed. As above mentioned, when a temperature distribution and an electrical distribution in the semiconductor laser array 1 are relaxed, thermal load and electrical load to a plurality of laser elements which are aligned in an array are uniformed, damage which is caused by high load to specific semiconductor laser element among a plurality of semiconductor laser elements can be controlled, as a result, a life as a semiconductor laser light source device can be prolonged.

### Embodiment 5

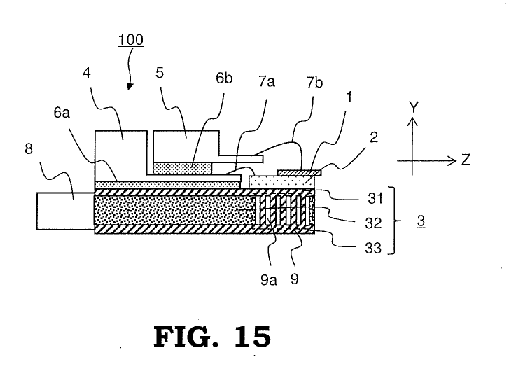

FIG. 15 is a sectional side view in an X-direction central part showing the configuration of a semiconductor laser light source device according to Embodiment 5 of present invention. In FIG. 15, in comparison with Embodiment 1, a semiconductor laser light source device according to Embodiment 5 in FIG. 15 has a heat sink whose shape is same as that of Embodiment 1, however, is different on the point such that a material of the heat sink 3 is a composite material. A heat sink 3 comprises a first heat sink member 31, a second heat sink member 32 and a third heat sink member 33, and a shape of a heat sink 3 is same as that of Embodiment 1, and has three-layered configuration which is made of a composite material. Other configuration is same as that of Embodiment 1, therefore description regarding the configuration to which the same number is given will be omitted. Ruther, a series of process for assembling a semiconductor laser light device and laser oscillation operation are same as those of Embodiment 1, therefore description will be omitted.

It is necessary for a surface on which a sub-mount substrate 2 is bonded on an upper surface of a heat sink and a square bar part having a comb-shape which are arranged so as to constitute a flat flow channel in a cooling part 9, as the first heat sink member 31 to be the first layer, to effectively dissipate heat which is generated by a semiconductor laser array 1 when the semiconductor laser array 1 oscillates. Therefore, the first heat sink member 31 is made of a material having excellent heat conductivity and whose heat transmission ratio is larger than that of the second heat sink member 32 which will be described in the following, for example, a metallic material such as Cu, etc. A part where a shape of water channel part is maintained, a cooling water channel 90 is formed and at which water channel coupling members 8 to be a cooling water entrance and exit are attached is made of the second heat sink member 32 which will be the second layer. On the other hand, a linear expansion coefficient of the semiconductor laser array 1 is generally much smaller than that of a cupper. Consequently, a linear expansion coefficient of the first heat sink member 31 becomes much larger than that of the semiconductor laser array 1. In order to make a linear expansion coefficient of the second heat sink member 32 to be smaller than that of the first heat sink member 31, by constituting the second heat sink member 32 with a material having a linear expansion coefficient which is smaller than that of the first heat sink member 31, a linear expansion coefficient of whole of the heat sink 3 is made to be closer to that of the semiconductor laser array 1 in comparison with a case in which whole of the heat sink 3 is constituted with same material as that of the first heat sink member. It is more preferable for the second heat sink member 32 to be constituted with a material having a linear expansion coefficient which is smaller than that of the semiconductor laser array 1, for example, a metallic material such as a molybdenum (hereinafter will be referred as Mo). The third heat sink member 33 which is a bottom surface of a lower surface and to be a third layer is constituted with a material which is the same as that of the first layer. Each layer is bonded with brazing, etc. A part where water flows may be plated. According to the above mentioned configuration, not only a flow channel having a flat shape but also a flow channel having complicated shape can be manufactured. Consequently, the configuration of a heat sink shown in FIG. 15 can be applied not only to a heat sink which comprises a flow channel having a flat shape having a large aspect ratio which is described in Embodiment 1, but also a heat sink having a conventional micro channel which is a flow channel having a small aspect ratio. Of course, the above-mentioned configuration can be applied to the heat sink 3 according to Embodiments 2 to 4. Further, other than metallic material, non-metallic material such as ceramics, carbon, diamond, sapphire, etc. may be used as a material of a heat sink.

According to the above mentioned configuration, in comparison with a case in which whole of the heat sink 3 is manufactured by using a material which is same as that of the first heat sink member 31, a linear expansion coefficient of whole of the heat sink 3 is reduced, as a result, a linear expansion coefficient can be made to be closer to that of the semiconductor laser array 1. Further, in a case where a linear expansion coefficient of the first heat sink member 31 is smaller than that of the semiconductor laser array 1, by constituting the second heat sink member 32 with a material which has a linear expansion coefficient which is larger than that of the first heat sink member 31, a linear expansion coefficient as whole of the heat sink 3 can be made to be closer to that of the semiconductor laser array 1.

According to a semiconductor laser light source device in Embodiment 5, a value of a linear expansion coefficient of a heat sink can be made to be closer to that of a semiconductor laser array, thermal stress which is generated when a member on which the semiconductor laser array 1 and the sub-mount substrate 2 are mounted is bonded on a heat sink by melting a solder material can be reduced. By reducing thermal stress, regarding a semiconductor laser light source, improvement of reliability in oscillating and a long life can be realized. Further, by applying to a heat sink which comprises a micro channel having a flat flow channel 9a having a large aspect ratio which was described in Embodiment 1, effect which was described in the Embodiment 1, that is, exhaust heat performance can be secured at a small flow velocity and erosion can be controlled, can be realized.

### Embodiment 6

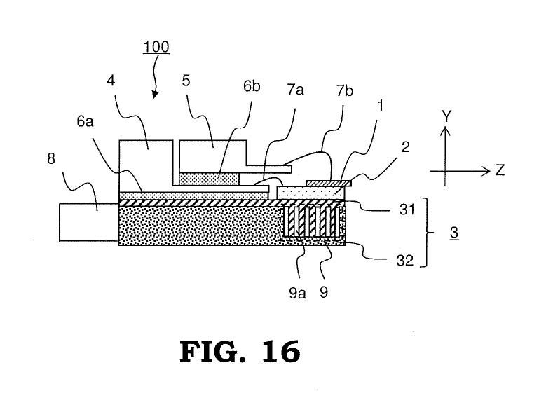

FIG. 16 is a sectional side view in an X-direction central part showing the configuration of a semiconductor laser light source device according to Embodiment 6 of present invention. In comparison with Embodiment 1, a semiconductor laser light source device according to Embodiment 6 in FIG. 16 has a heat sink whose shape is same as that of Embodiment 1, however, is different on the point such that a material of the heat sink 3 is a composite material. The heat sink 3 comprises a first heat sink member 31 and a second heat sink member 32 and has the same shape as that of a heat sink 3 according to Embodiment 1 and has two-layered configuration constituted with a composite material. The heat sink 3 according to Embodiment 5 has three-layered configuration, however, the heat sink 3 according to Embodiment 6 has two-layered configuration. Other configuration is same as that of Embodiment 1, therefore description regarding the configuration to which the same number is given will be omitted. Further, a series of process for assembling a semiconductor laser light device and laser oscillation operation are same as those of Embodiment 1, therefore description will be omitted.

It is necessary for a surface on which a sub-mount substrate 2 is bonded on an upper surface of a heat sink and a square bar part having a comb-shape which are arranged so as to constitute a flat flow channel in a cooling part 9, as the first heat sink member 31 to be the first layer, to effectively dissipate heat which is generated by a semiconductor laser array 1 when the semiconductor laser array 1 oscillates. Therefore, in the same way as that of a first heat sink member 31 according to Embodiment 5, the first heat sink member 31 is made of a material having excellent heat conductivity and whose heat transmission ratio is larger than that of the second heat sink member 32, for example, a metallic material such as Cu, etc. A part where a shape of water channel part is maintained, a cooling water channel 90 is formed and at which water channel coupling members 8 to be a cooling water entrance and exit are attached, and a part which corresponds to a lower surface of a bottom plate which is formed by using the same material as that of a first heat sink member 31 in Embodiment 5 are constituted with the second heat sink member 32 to be the second layer. In a case where the first heat sink member 31 is constituted with a material whose heat transmission ratio is large such as Cu, generally, a linear expansion coefficient of the first heat sink member 31 becomes larger than that of the semiconductor laser array 1. By constituting the second heat sink member 32 with a material having a linear expansion coefficient which is smaller than that of the first heat sink member 31 in the same way as that of the second heat sink member 32 according to Embodiment 5, a linear expansion coefficient of whole of the heat sink 3 is made to be closer to that of the semiconductor laser array 1 in comparison with a case in which whole of the heat sink 3 is constituted with same material as that of the first heat sink member. It is more preferable for the second heat sink member 32 to be constituted with a material having a linear expansion coefficient which is smaller than that of the semiconductor laser array 1, for example, a metallic material such as a molybdenum (hereinafter will be referred as Mo). The first heat sink member 31 and the second heat sink member are bonded by brazing, etc. A part where water flows may be plated. The configuration of a heat sink shown in FIG. 16 can be applied not only to a heat sink which comprises a flow channel having a flat shape having a large aspect ratio which is described in Embodiment 1, but also a heat sink having a conventional micro channel which is a flow channel having a small aspect ratio. Of course, the above-mentioned configuration can be applied to the heat sink 3 according to Embodiments 2 to 4. Further, other than metallic material, non-metallic material such as ceramics, carbon, diamond, sapphire, etc. may be used as a material of a heat sink.

According to the above mentioned configuration, in comparison with a case in which whole of the heat sink 3 is manufactured by using a material which is same as that of the first heat sink member 31, a linear expansion coefficient of whole of the heat sink 3 is reduced, therefore, a linear expansion coefficient can be made to be closer to that of the semiconductor laser array 1. Further, in a case where a linear expansion coefficient of the first heat sink member 31 is smaller than that of the semiconductor laser array 1, by constituting the second heat sink member 32 with a material which has a linear expansion coefficient which is larger than that of the first heat sink member 31, a linear expansion coefficient as whole of the heat sink 3 can be made to be closer to that of a linear expansion coefficient of the semiconductor laser array 1.

According to a semiconductor laser light source device in Embodiment 6, a value of a linear expansion coefficient of a heat sink can be made to be closer to that of a semiconductor laser array, thermal stress which is generated when a member on which the semiconductor laser array 1 and the sub-mount substrate 2 are mounted is bonded on the heat sink by melting a solder material can be reduced. By reducing thermal stress, regarding a semiconductor laser light source, improvement of reliability in oscillating and a long life can be realized. Further, by applying to a heat sink which comprises a micro channel having a flat flow channel 9a having a large aspect ratio which is described in Embodiment 1, effect which was described in the Embodiment 1, that is, exhaust heat performance can be secured at a small flow velocity and erosion can be controlled, can be realized

Further, it is understood that the form of each embodiment may be combined or the form of each embodiment may be changed or omitted without departing from the spirit of essential characteristics thereof.

### DESCRIPTION OF REFERENCE CHARACTER

1: semiconductor laser array
1a: edge part of a semiconductor laser array
2: sub-mount substrate
3: heat sink
4: first electrode plate
5: second electrode plate
6a: first insulation plate
6b: second insulation plate
7a, 7b: metallic wire
9: cooling part
9a: flat flow channel
90: cooling water channel
10: cooling block
13: indirect substrate
31: first heat sink member
32: second heat sink member
33: third heat sink member

1. A semiconductor laser light source device wherein a plate-shaped semiconductor laser array, which has a plurality of semiconductor laser elements that are aligned in an array form, has a first electrode that is formed on one surface and a second electrode that is formed on the other surface, the first electrode is bonded to an electrode layer of a sub-mount substrate in which the electrode layer is formed on one surface of a substrate formed of electrical insulation material and the sub-mount substrate surface which is a surface opposite to a surface on which the electrode layer is formed is bonded to a heat sink made of metal,
in a case where a direction which is perpendicular to a surface on which the sub-mount substrate is bonded is defined as a Y direction, a direction which is perpendicular to the Y-direction and where a plurality of laser elements of a semiconductor laser array are aligned is defined as an X direction and a direction which is perpendicular to the Y direction and the X direction is defined as a Z direction,
in a region which is formed by projecting the sub-mount substrate to inside of the heat sink from the Y direction, a cooling part wherein a plurality of flat flow channels having a width of 200 μm to 600 μm in the Z direction, a depth of 3 mm to 5 mm in the Y direction are aligned at a pitch equal to or less than 1 mm in the Z direction is formed, and in order for cooling water to flow from one side of the X direction of the cooling part to the other, two cooling water channels for communicating with the cooling part from outside of the heat sink are provided.

2. The semiconductor laser light source device according to claim 1, wherein on a surface of the heat sink which is a surface opposite to a surface on which the sub-mount substrate is bonded, a cooling block, for the cooling water to flow in from one of the cooling water channel, among the two cooling water channels, and flow out from other cooling water channel, is provided.

3. The semiconductor laser light source device according to claim 1, wherein a first electrode plate is fixed, in a region of a surface of the heat sink, on which the sub-mount substrate is bonded, which is different from a region on which the sub-mount substrate is bonded, via a first insulation plate, a second electrode plate is fixed on a surface of the first electrode plate which is a surface opposite to the heat sink via a second insulation plate, the electrode layer of the sub-mount substrate and the first electrode plate are connected by a metallic wire and the second electrode of the semiconductor laser array and the second electrode plate are connected by a metallic wire.

4. The semiconductor laser light source device according to claim 1, wherein a first electrode plate is fixed, in a region of a surface of the heat sink, on which the sub-mount substrate is bonded, which is different from a region on which the sub-mount substrate is bonded, via a first insulation plate, a second electrode plate is fixed on a surface of the first electrode plate which is a surface opposite to the heat sink via a second insulation plate, a conductive indirect substrate is bonded on the second electrode of the semiconductor laser array, the electrode layer of the sub-mount substrate and the first electrode plate are connected by a metallic wire and the indirect substrate and the second electrode plate are connected by a metallic wire.

5. The semiconductor laser light source device according to claim 3, wherein the first electrode plate and the second electrode plate are fixed to the heat sink by an insulation screw or a screw which is insulated by a insulation bush.

6. The semiconductor laser light source device according to claim 1, wherein material of the sub-mount substrate is silicon carbide or aluminum nitride.

7. The semiconductor laser light source device according to claim 1, wherein at least a part of the heat sink from a part which constitutes the flat flow channel to a surface on which the semiconductor laser array is bonded is constituted with a first heat sink member, a part of the heat sink which forms the cooling water channels is constituted with a second heat sink member which is bonded to the first heat sink member, and a heat transmission ratio of the first heat sink member is larger than a heat transmission ratio of the second heat sink member,
in a case where a linear expansion coefficient of the first heat sink member is larger than a linear expansion coefficient of the semiconductor laser array, the second heat sink member is constituted with material having a linear expansion coefficient which is smaller than a linear expansion coefficient of the first heat sink member,
in a case where a linear expansion coefficient of the first heat sink member is smaller than a linear expansion coefficient of the semiconductor laser array, the second heat sink member is constituted with member having a linear expansion coefficient which is larger than a linear expansion coefficient of the first heat sink member.

8. The semiconductor laser light source device according to claim 7, wherein a part of the heat sink from a part which constitutes the flat flow channel to a surface on which the semiconductor laser array is bonded is constituted with a first heat sink member, a part of the heat sink which forms the cooling water channels is constituted with a second heat sink member, a part of the heat sink which is a bottom plate which is opposite to a side where the sub-mount substrate is bonded is constituted with a third heat sink member which is formed with material which is same as the first heat sink member and is bonded to the second heat sink member.

9. A semiconductor laser light source device wherein a plate-shaped semiconductor laser array, which has a plurality of semiconductor laser elements that are aligned in an array form, has a first electrode that is formed on one surface and a second electrode that is formed on the other surface, the first electrode is bonded to an electrode layer of a sub-mount substrate in which the electrode layer is formed on one surface of a substrate formed of electrical insulation material and the sub-mount substrate surface which is a surface opposite to a surface on which the electrode layer is formed is bonded to a heat sink made of metal,
in a case where a direction which is perpendicular to a surface on which the sub-mount substrate is bonded is defined as a Y direction, a direction which is perpendicular to the Y-direction and where a plurality of laser elements of a semiconductor laser array are aligned is defined as an X direction and a direction which is perpendicular to the Y direction and the X direction is defined as a Z direction,
in a region which is formed by projecting the sub-mount substrate to inside of the heat sink from the Y direction, a cooling part wherein a plurality of flow channels are aligned in the Z direction is formed, and in order for cooling water to flow from one side of the X direction of the cooling part to the other, two cooling water channels for communicating with the cooling part from outside of the heat sink are provided,
wherein at least a part of the heat sink from a part which constitutes the plurality of flow channels to a surface on which the semiconductor laser array is bonded is constituted with a first heat sink member, a part of the heat sink which forms the cooling water channels is constituted with a second heat sink member which is bonded to the first heat sink member, and a heat transmission ratio of the first heat sink member is larger than a heat transmission ratio of the second heat sink member,
in a case where a linear expansion coefficient of the first heat sink member is larger than a linear expansion coefficient of the semiconductor laser array, the second heat sink member is constituted with material having a linear expansion coefficient which is smaller than a linear expansion coefficient of the first heat sink member,
in a case where a linear expansion coefficient of the first heat sink member is smaller than a linear expansion coefficient of the semiconductor laser array, the second heat sink member is constituted with material having a linear expansion coefficient which is larger than a linear expansion coefficient of the first heat sink member.

10. The semiconductor laser light source device according to claim 9, wherein a part of the heat sink which is a bottom plate which is opposite to a side where the sub-mount substrate is bonded is constituted with a third heat sink member which is formed with material which is same as the first heat sink member and is bonded on the second heat sink member.

11. The semiconductor laser light source device according to claim 2, wherein a first electrode plate is fixed, in a region of a surface of the heat sink, on which the sub-mount substrate is bonded, which is different from a region on which the sub-mount substrate is bonded, via a first insulation plate, a second electrode plate is fixed on a surface of the first electrode plate which is a surface opposite to the heat sink via a second insulation plate, the electrode layer of the sub-mount substrate and the first electrode plate are connected by a metallic wire and the second electrode of the semiconductor laser array and the second electrode plate are connected by a metallic wire.

12. The semiconductor laser light source device according to claim 2, wherein a first electrode plate is fixed, in a region of a surface of the heat sink, on which the sub-mount substrate is bonded, which is different from a region on which the sub-mount substrate is bonded, via a first insulation plate, a second electrode plate is fixed on a surface of the first electrode plate which is a surface opposite to the heat sink via a second insulation plate, a conductive indirect substrate is bonded on the second electrode of the semiconductor laser array, the electrode layer of the sub-mount substrate and the first electrode plate are connected by a metallic wire and the indirect substrate and the second electrode plate are connected by a metallic wire.

13. The semiconductor laser light source device according to claim 4, wherein the first electrode plate and the second electrode plate are fixed to the heat sink by an insulation screw or a screw which is insulated by a insulation bush.

14. The semiconductor laser light source device according to claim 11, wherein the first electrode plate and the second electrode plate are fixed to the heat sink by an insulation screw or a screw which is insulated by a insulation bush.

15. The semiconductor laser light source device according to claim 12, wherein the first electrode plate and the second electrode plate are fixed to the heat sink by an insulation screw or a screw which is insulated by a insulation bush.

16. The semiconductor laser light source device according to claim 1, wherein material of the heat sink is copper
